(19) United States
(12) Patent Application Publication
(10) Pub. No.: US 2026/0163592 A1
(43) Pub. Date: Jun. 11, 2026

(54) SIGNAL PROCESSING DEVICE AND SIGNAL TRANSCEIVING DEVICE

(71) Applicant: RichWave Technology Corp., Taipei (TW)

(72) Inventor: Ting-Yuan Cheng, Taipei (TW)

(73) Assignee: RichWave Technology Corp., Taipei (TW)

(21) Appl. No.: 19/000,739

(22) Filed: Dec. 24, 2024

(30) Foreign Application Priority Data
Dec. 5, 2024 (TW) 113147186

(51) Int. Cl. H04B 1/00; H03F 3/38; H04B 1/04

(52) U.S. Cl. CPC H04B 1/0078; H03F 3/38; H04B 1/04; H03F 2200/372; H04B 2001/0408

(57) ABSTRACT

A signal processing device and a signal transcciving device are provided. The signal processing device includes a first amplifier, two first choppers, a second chopper, and a third chopper. The first amplifier is configured to generate a second signal according to a first signal. The two first choppers are embedded between an input end and an output end of the first amplifier and respectively configured to perform a shifting operation of a first frequency and a shifting back operation of the first frequency. The second chopper is coupled to the input end of the first amplifier and configured to perform a shifting operation of a second frequency. The third chopper is coupled to the output end of the first amplifier and configured to perform a shifting back operation of the second frequency. The first frequency and the second frequency are different.

### CROSS-REFERENCE TO RELATED APPLICATION

This application claims the priority benefit of Taiwan application serial no. 113147186, filed on December 5, 2024. The entirety of the above-mentioned patent application is hereby incorporated by reference herein and made a part of this specification.

### BACKGROUND

### Technical Field

The disclosure relates to a signal processing device and a signal transceiving device, and in particular to a signal processing device and a signal transceiving device which may improve quality of a transmitted signal.

### Related Art

In a signal transceiving device, such as a radar system, when a receiving circuit and a transmitting circuit in the signal transceiving device are simultaneously enabled, the receiving circuit and the transmitting circuit transmit signals simultaneously, and an input signal received by the receiving circuit may have a problem of DC offset value. The DC offset value may come from radiation phenomena on a printed circuit board and be generated by coupling of a substrate. In addition, a low-frequency flicker noise present on the input signal is also an important factor affecting quality of signal transmission.

### SUMMARY

The disclosure provides a signal processing device and a signal transceiving device which may effectively improve a signal to noise ratio (SNR) of a transmitted signal.

A signal processing device of the disclosure includes a first amplifier, two first choppers, a second chopper, and a third chopper. The first amplifier is configured to generate a second signal according to a first signal. The two first choppers are embedded between an input end and an output end of the first amplifier. The two first choppers are configured to perform a shifting operation of a first frequency and a shifting back operation of the first frequency, respectively. The second chopper is coupled to the input end of the first amplifier. The third chopper is coupled to the output end of the first amplifier. The second chopper is configured to perform a shifting operation of a second frequency. The third chopper is configured to perform a shifting back operation of the second frequency. The first frequency and the second frequency are different.

A signal transceiving device of the disclosure includes a transmitting circuit and a receiving circuit. The transmitting circuit is configured to continuously transmit a transmission signal during a first period. The receiving circuit is configured to continuously receive an input signal during the first period. The input signal is generated by the transmission signal being reflected by an external object. The receiving circuit includes the signal processing device as described above.

Based on the above, in the signal processing device of the disclosure, multiple choppers are disposed between the input end and output end of the amplifier, and on the input end and output end of the amplifier, respectively. By these choppers performing the shifting operation and the shifting back operation of different frequencies, the DC offset value of the transmitted signal may be removed and the low-frequency flicker noise may be reduced, thereby effectively improving the signal quality of the received signal.

### BRIEF DESCRIPTION OF THE DRAWINGS

FIG. 1, FIG. 2A, FIG. 2B, FIG. 3A, and FIG. 3B are schematic diagrams of signal processing devices of multiple embodiments of the disclosure.

FIG. 4 is a schematic diagram of a signal transceiving device of an embodiment of the disclosure.

### DESCRIPTION OF THE EMBODIMENTS

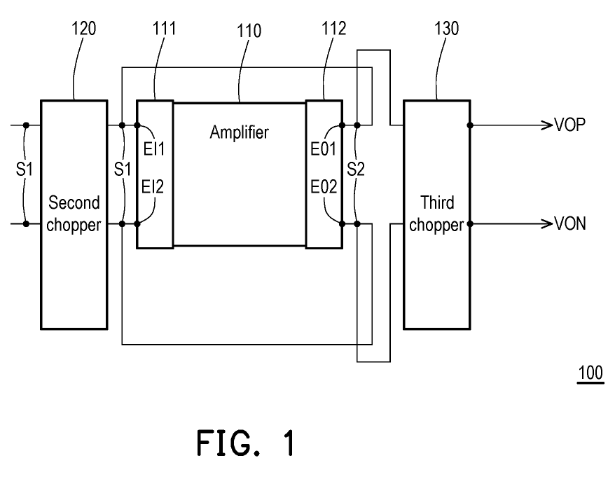

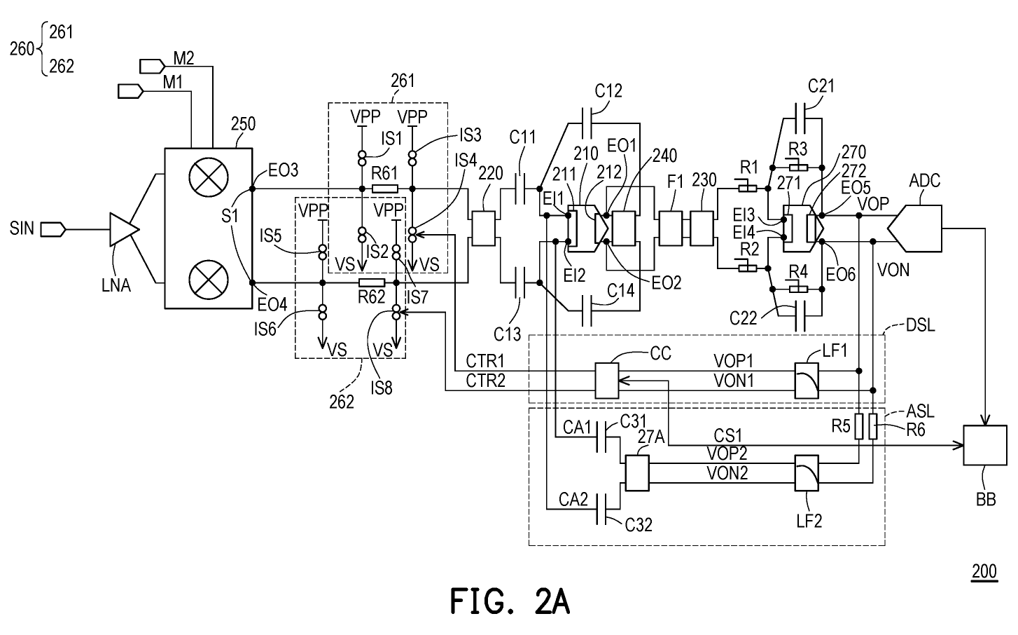

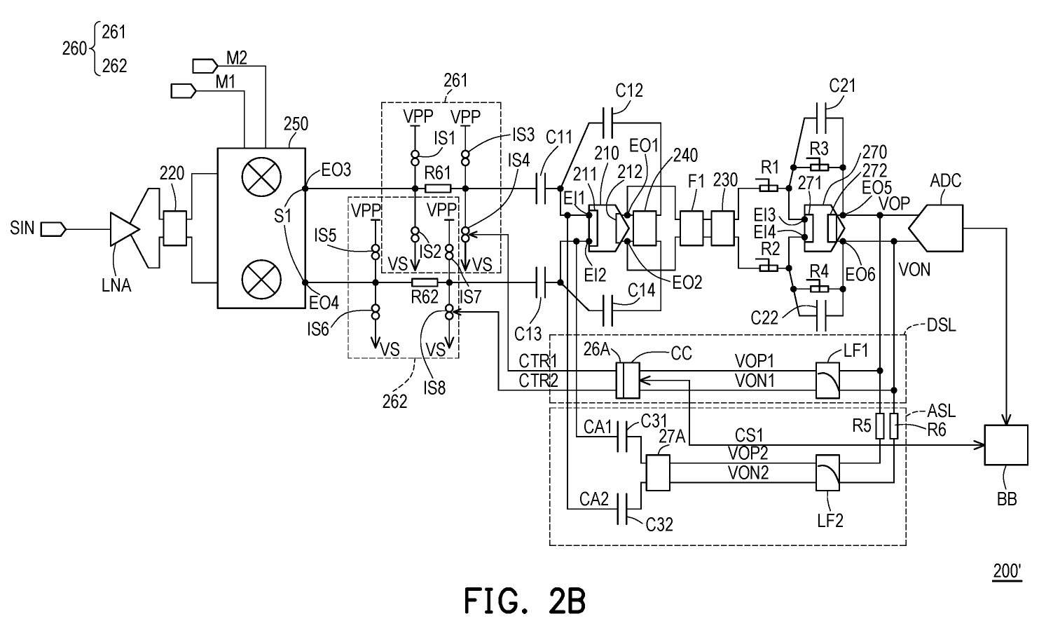

Please refer to FIG. 1, which is a schematic diagram of a signal processing device of an embodiment of the disclosure. A signal processing device 100 includes an amplifier 110, first choppers 111 and 112, a second chopper 120, and a third chopper 130. The amplifier 110 receives a signal S1 by input ends EI1 and EI2, and may generate a signal S2 according to the signal S1. Furthermore, the amplifier 110 may generate the signal S2 by amplifying the signal S1 on output ends EO1 and EO2. In this embodiment, the signal S1 may have two sub-signals with complementary phases. Correspondingly, the signal S2 may also have two sub-signals with complementary phases. The first choppers 111 and 112 are embedded between the input ends EI1 and EI2 and the output ends EO1 and EO2 of the amplifier 110. Specifically, the first chopper 111 is coupled to the input ends EI1 and EI2 of the amplifier 110, while the first chopper 112 is coupled to the output ends EO1 and EO2 of the amplifier 110.

Moreover, the second chopper 120 is disposed outside the amplifier 110 and is coupled to the input ends EI1 and EI2 of the amplifier 110. The third chopper 130 is disposed outside the amplifier 110 and is coupled to the output ends EO1 and EO2 of the amplifier 110. In detail, an input end of the third chopper 130 may be coupled to the output ends EO1 and EO2 of the amplifier 110, while an output end of the third chopper 130 generates output signals VOP and VON.

In this embodiment, the first chopper 111 may perform a shifting operation of a frequency on the signal S1 at the input ends EI1 and EI2 of the amplifier 110, while the first chopper 112 may perform a shifting back operation of the frequency on the signal S2 at the output ends EO1 and EO2 of the amplifier 110. The first chopper 111 and the first chopper 112 jointly perform a chopping control of a first frequency. For example, the first chopper 111 may execute an adjustment action to increase a frequency of the signal S1 to the first frequency, and correspondingly, the first chopper 112 may execute an adjustment action to decrease a frequency of the signal S2 to the original frequency. Alternatively, the first chopper 111 may execute an adjustment action to decrease the frequency of the signal S1 to the first frequency, and correspondingly, the first chopper 112 may execute an adjustment action to increase the frequency of the signal S2 to the original frequency.

The second chopper 120 receives the signal S1 and may execute a shifting operation of the second frequency on the signal S1. The third chopper 130 receives the signal S2 and is configured to execute a shifting back operation of the second frequency on the signal S2. The second chopper 120 and the third chopper 130 jointly perform a chopping control of the second frequency. Specifically, the second chopper 120 may execute an adjustment action to increase the frequency of the signal S1 to the second frequency, and correspondingly, the third chopper 130 may execute an adjustment action to decrease the frequency of the signal S2 to the original frequency. Alternatively, the second chopper 120 may execute an adjustment action to decrease the frequency of the signal S1 to the second frequency, and correspondingly, the third chopper 130 may execute an adjustment action to increase the frequency of the signal S2 to the original frequency. It is worth mentioning that the aforementioned first frequency and second frequency are not equal. The first frequency and the second frequency are usually selected as the frequency of the noise to be removed. For example, the first frequency and the second frequency differ by at least two times, so that noise of different frequencies may be removed. Furthermore, the first frequency may be, for example, 12.5 megahertz (MHz), and the second frequency may be, for example, 3 MHz or 6 MHz.

In this embodiment, the first choppers 111 and 112 to the third chopper 130 are disposed at multiple locations in the circuit of the signal processing device 100. Through a switching actions performed by the first choppers 111 and 112 to the third chopper 130, DC offset values and flicker noise on each signal S1 and S2 may be effectively eliminated. It is worth noting that in this embodiment, the first choppers 111 and 112 disposed between the input ends EI1 and EI2 and the output ends EO1 and EO2 of the amplifier 110 may effectively eliminate the DC offset values and flicker noise of the signals transmitted in this interval, and reduce the possibility of signal errors caused by amplification of the DC offset values and/or flicker noise, thereby improving accuracy and stability of the output signals VOP and VON.

Taking a radar system as an example, based on a fact that DC offset values and flicker noise may be coupled into the signal transceiver device from a printed circuit board, the DC offset values that may enter therefore may be effectively eliminated by disposing the first choppers 111 and 112 to the third chopper 130.

Moreover, in this embodiment, the output signals VOP and VON may be maintained at the target frequency by disposing paired first choppers 111 and 112, and paired second chopper 120 and third chopper 130.

It is worth mentioning that the first choppers 111 and 112, the second chopper 120, and the third chopper 130 in this embodiment of the disclosure may all be implemented by using chopper circuits well known to those skilled in the art, without specific limitations.

The following description refers to FIG. 2A. FIG. 2A is a schematic diagram of a signal processing device according to another embodiment of the disclosure. A signal processing device 200 includes amplifiers 210 and 270, a mixer 250, first choppers 211 and 212, a second chopper 220, a third chopper 230, a fourth chopper 240, fifth choppers 271 and 272, a filter F1, an analog-to-digital converter ADC, a DC offset circuit 260, a low noise amplifier LNA, and feedback circuits DSL and ASL.

In this embodiment, the mixer 250 is coupled to input ends EI1 and EI2 of the amplifier 210, and is configured to perform frequency mixing on an input signal SIN to generate the signal S1. Specifically, the low noise amplifier LNA receives the input signal SIN, and the mixer 250 is coupled to the low noise amplifier LNA to receive an output signal of the low noise amplifier LNA. The mixer 250 performs a wave mixing action on the output signal of the low noise amplifier LNA according to phase-complementary reference signals M1 and M2, and generates the signal S1. The signal S1 includes two phase-complementary sub-signals.

The DC offset circuit 260 is coupled to the input ends EI1 and EI2 of the amplifier 210, and is configured to adjust a DC voltage level of the signal S1 according to control signals (including a control signal CTR1 and a control signal CTR2). The DC offset circuit 260 is coupled to an output end of the mixer 250. The DC offset circuit 260 includes sub-circuits 261 and 262. The sub-circuit 261 receives a first sub-signal of the signal S1. The sub-circuit 261 includes current sources IS1 to IS4 and a resistor R61. The current source IS1 is coupled between a power supply voltage VPP and an output end EO3 of the mixer 250. The current source IS2 is coupled between the output end EO3 of the mixer 250 and a reference voltage VS. The current source IS3 is coupled between the power supply voltage VPP and the input end EI1 of the amplifier 210. The current source IS4 is coupled between the input end EI1 of the amplifier 210 and the reference voltage VS. The resistor R61 is coupled between the output end EO3 of the mixer 250 and the input end EI1 of the amplifier 210.

The sub-circuit 262 receives a second sub-signal of the signal S1. The sub-circuit 262 includes current sources IS5 to IS8 and a resistor R62. The current source IS5 is coupled between the power supply voltage VPP and an output end EO4 of the mixer 250. The current source IS6 is coupled between the output end EO4 of the mixer 250 and the reference voltage VS. The current source IS7 is coupled between the power supply voltage VPP and the input end EI2 of the amplifier 210. The current source IS8 is coupled between the input end EI2 of the amplifier 210 and the reference voltage VS. The resistor R62 is coupled between the output end EO4 of the mixer 250 and the input end EI2 of the amplifier 210.

In this embodiment, the current source IS4 may receive the control signal CTR1 and adjust an output current value according to the control signal CTR1, thereby adjusting a DC offset value of the first sub-signal of the signal S1. The current source IS8 may receive the control signal CTR2 and adjust the output current value according to the control signal CTR2, thereby adjusting a DC offset value of the second sub-signal of the signal S1.

In other embodiments of the disclosure, the control signal CTR1 may also be provided to any one of the current sources IS1, IS2, and IS3, and the DC offset value of the first sub-signal of the signal S1 is adjusted by adjusting the current value provided by any one of the current sources IS1, IS2, and IS3. Similarly, the control signal CTR2 may also be provided to any one of the current sources IS5, IS6, and IS7, and the DC offset value of the second sub-signal of the signal S1 is adjusted by adjusting the current value provided by any one of the current sources IS5, IS6, and IS7.

The second chopper 220 is coupled between the output ends EO3 and EO4 of the mixer 250 and the input ends EI1 and EI2 of the amplifier 210. Furthermore, the second chopper 220 is coupled between the DC offset circuit 260 and the amplifier 210. The second chopper 220 may be coupled to the input ends EI1 and EI2 of the amplifier 210 through capacitors C11 and C13. The first choppers 211 and 212 are embedded between the input ends EI1 and EI2 and the output ends EO1 and EO2 of the amplifier 210. The first chopper 211 is coupled to the input ends EI1 and EI2, while the first chopper 212 is coupled to the output ends EO1 and EO2.

The fourth chopper 240 is coupled between the output ends EO1 and EO2 and the input ends EI1 and EI2 of the amplifier 210. Furthermore, the input ends of the fourth chopper 240 are coupled to the output ends EO1 and EO2 of the amplifier 210, while the two output ends of the fourth chopper 240 are coupled to the input ends EI1 and EI2 of the amplifier 210 through capacitors C12 and C14 respectively. The fourth chopper 240 is disposed outside the amplifier 210. It is worth noting that a series of capacitors including capacitors C11 and C12 is coupled between the output end EO1 and the input end EI1 of the amplifier 210, a series of capacitors including capacitors C13 and C14 is coupled between the output end EO2 and the input end EI2 of the amplifier 210, and a series of capacitors including capacitors C11 and C12 and a series of capacitors including capacitors C13 and C14 in conjunction with the amplifier 210 may form a capacitively coupled instrumentation amplifier (CCIA). Compared to a conventional amplifier using a resistor, the architecture of the disclosure using the CCIA may reduce thermal noise which may be generated by disposing the resistor.

The third chopper 230 is coupled to the output ends EO1 and EO2 of the amplifier 210 through the filter F1. In this embodiment, the output ends of the third chopper 230 may be coupled to another amplifier 270. The amplifier 270 is coupled to the amplifier 210 and configured to generate the output signals VOP and VON according to the signal S2. The fifth choppers 271 and 272 may be embedded between the input ends EI3 and EI4 and the output ends EO5 and EO6 of the amplifier 270. The fifth chopper 271 is coupled to the input ends EI3 and EI4 of the amplifier 270, and the fifth chopper 272 is coupled to the output ends EO5 and EO6 of the amplifier 270. Here, the third chopper 230 may be coupled to the input ends EI3 and EI4 of the amplifier 270 through resistors R1 and R2 respectively. The middle between the input ends EI3 and EI4 and the output ends EO5 and EO6 of the amplifier 270 may be coupled to resistors R3 and R4 and capacitors C21 and C22 respectively. The capacitor C21 is in parallel with the resistor R3, and the capacitor C22 is in parallel with the resistor R4. In this embodiment, the resistors R1 to R4 may be variable resistors. Furthermore, for example, when a gain of the transmitted signal needs to be changed, resistance values of the resistors R1 to R4 may be changed according to the required gain.

Similar to the embodiment of FIG. 1, in this embodiment, the first chopper 211, the second chopper 220, the fourth chopper 240, and the fifth chopper 271 may be configured to perform a shifting operation of a frequency on the signal, while the first chopper 212, the third chopper 230, and the fifth chopper 272 may be configured to perform a shifting back operation of the frequency on the signal. The relevant details of the operations of the first choppers 211 and 212, the second chopper 220, and the third chopper 230 are described in the embodiment of FIG. 1, and are not repeated here. In another aspect, the fourth chopper 240 and the third chopper 230 jointly perform a chopping control of the second frequency. Specifically, the fourth chopper 240 is configured to perform a shifting operation of the second frequency on the transmitted signal, and correspondingly, the third chopper 230 may be configured to perform a shifting back operation of the second frequency on the transmitted signal. Similarly, the shifting operation of the second frequency of the fourth chopper 240 may increase or decrease the frequency of the transmitted signal by the second frequency, which may be set up by engineers. Moreover, the fifth chopper 271 and the fifth chopper 272 jointly perform a chopping control of the first frequency. For example, the fifth chopper 271 may execute an adjustment action to increase the frequency of the transmitted signal to the first frequency, and correspondingly, the fifth chopper 272 may execute an adjustment action to decrease the frequency of the transmitted signal to the original frequency. Alternatively, the fifth chopper 271 may execute an adjustment action to decrease the frequency of the transmitted signal to the first frequency, and correspondingly, the fifth chopper 272 may execute an adjustment action to increase the frequency of the transmitted signal to the original frequency.

In this embodiment, the output ends EO5 and EO6 of the amplifier 270 generate the output signals VOP and VON respectively, and the output signals VOP and VON are transmitted to the analog-to-digital converter ADC. The analog-to-digital converter ADC is configured to convert the output signals VOP and VON in an analog format to a digital format, and transmit the output signals VOP and VON in the digital format to a baseband device BB.

In another aspect, a feedback circuit DSL is coupled between the output ends EO5 and EO6 of the amplifier 270 and the DC offset circuit 260. The feedback circuit DSL is configured to generate control signals CTR1 and CTR2 according to the output signals VOP and VON. The feedback circuit DSL includes a low-pass filter LF1 and a compensation circuit CC. The low-pass filter LF1 is configured to receive the output signals VOP and VON and generate filtered output signals VOP1 and VON1 respectively. The compensation circuit CC processes the filtered output signals VOP1 and VON1 to generate digital control signals CTR1 and CTR2 based on a calibration signal CS1. In this embodiment, the calibration signal CS1 is, for example, a baseband signal provided by the baseband device BB.

A feedback circuit ASL is coupled between the output ends EO5 and EO6 of the amplifier 270 and the input ends EI1 and EI2 of the amplifier 210. The feedback circuit ASL includes a capacitor pair composed of capacitors C31 and C32, a low-pass filter LF2, and a seventh chopper 27A. The low-pass filter LF2 receives the output signals VOP and VON by resistors R5 and R6 respectively and generates filtered output signals VOP2 and VON2.

The capacitor pair composed of the capacitors C31 and C32 is serially coupled with the seventh chopper 27A between the low-pass filter LF2 and the input ends EI1 and EI2 of the amplifier 210, and configured to generate compensation signals CA1 and CA2 according to the filtered output signals VOP2 and VON2, and the compensation signals CA1, CA2 are transmitted to the input ends EI2 and EI1 of the amplifier 210. It is worth noting that the seventh chopper 27A and the third chopper 230 jointly perform a chopping control of the second frequency. Specifically, the seventh chopper 27A is configured to perform a shifting operation of the second frequency on the transmitted signal, and correspondingly, the third chopper 230 is configured to perform a shifting back operation of the second frequency on the transmitted signal. In addition, the capacitors C31 and C32 are paired with the aforementioned CCIA formed by the capacitors C11, C12, C13, and C14, and amplifier 210. In this way, the capacitive electronic components are used in a transmission path of the feedback compensation signals CA1 and CA2 to reduce thermal noise more effectively compared to the resistors.

It may be noted that in this embodiment, the static and dynamic DC offset values coupled into the circuit may be effectively eliminated by the choppers 220, 211, 212, 230, 240, 271, and 272 corresponding to different frequencies. Furthermore, the residual DC offset values in the circuit may be further eliminated by the chopper 27A in the analog format feedback circuit ASL, thereby optimizing the performance of the signal transceiver device.

Please refer to FIG. 2B, which is a schematic diagram of a signal processing device according to another embodiment of the disclosure. A signal processing device 200’ has similar circuit components to the signal processing device 200 in FIG. 2A, where the same parts are not repeated. The difference between the signal processing device 200’ and the signal processing device 200 lies in that the second chopper 220 is coupled between the mixer 250 and the low noise amplifier LNA in the signal processing device 200’. More specifically, the second chopper 220 is coupled to an input of the mixer 250 and an output of the low noise amplifier LNA. In this way, the flicker noise generated by the mixer 250 may be first shifted to the second frequency (shifted out), and then paired with another third chopper 230 to perform the shifting back operation of the frequency. In addition, compared to the signal processing device 200, a sixth chopper 26A may be disposed at an output of the compensation circuit CC in the signal processing device 200’. The sixth chopper 26A and the third chopper 230 jointly perform a chopping control of the second frequency. Furthermore, the sixth chopper 26A may be configured to perform a shifting operation of the second frequency on the transmitted signal, while the third chopper 230 may be configured to perform a corresponding shifting back operation of the second frequency on the transmitted signal. The residual DC offset values in the circuit may be further eliminated by the chopper 26A in the digital format feedback circuit DSL, thereby optimizing the performance of the signal transceiver device.

Please refer to FIG. 3A, which is a schematic diagram of a signal processing device according to another embodiment of the disclosure. A signal processing device 300 has a circuit architecture similar to the circuit architecture of the signal processing device 200 in FIG. 2A. Compared to the signal processing device 200, the signal processing device 300 has a different feedback circuit DSL. The signal processing device 300 does not include the DC offset circuit 260 disposed in the signal processing device 200, and the second chopper 220 of the signal processing device 300 is directly coupled to the mixer 250. In this embodiment, the relevant details of the embodiment of the parts that are the same as those in the signal processing device 200 in FIG. 2A may be referred to in the embodiment of FIG. 2A, and are not repeated here.

In this embodiment, the feedback circuit DSL includes partial circuits DSL-1 and DSL-2. The feedback circuit DSL is coupled between the output ends EO5 and EO6 of the amplifier 270 and the input ends EI1 and EI2 of the amplifier 210. The feedback circuit DSL provides compensation signals CA3 and CA4 to the input ends EI2 and EI1 of the amplifier 210 according to the output signals VOP and VON. The partial circuit DSL-1 includes a low-pass filter LF31. The low-pass filter LF31 receives the output signals VOP and VON, and generates filtered output signals VOP1 and VOP2. The partial circuit DSL-2 includes a logic circuit 310, capacitors CB1 and CB2, and a sixth chopper 360. The logic circuit 310 converts the filtered output signals VOP1 and VON1 into a digital conversion signal SB3 based on the calibration signal CS1, and according to a shared voltage Vcm and a reference voltage Vref. In this embodiment, the calibration signal CS1 may be, for example, a baseband signal provided by the baseband device BB.

The capacitors CB1 and CB2 form a capacitor pair. The capacitor pair and the sixth chopper 360 are serially coupled between the logic circuit 310 and the input ends EI1 and EI2 of the amplifier 210. The sixth chopper 360 and the third chopper 230 jointly perform a chopping control of the second frequency. Furthermore, the sixth chopper 360 may be configured to receive the conversion signal SB3 and generate compensation signals CA3 and CA4. The sixth chopper 360 may be configured to perform a shifting operation of the second frequency on the transmitted signal, and correspondingly, the third chopper 230 may be configured to perform a shifting back operation of the second frequency on the transmitted signal.

In this embodiment, the logic circuit 310 may be a successive-approximation (SAR) analog-to-digital converter.

Please refer to FIG. 3B, which is a schematic diagram of a signal processing device according to another embodiment of the disclosure. A signal processing device 300’ has similar circuit components to the signal processing device 300 in FIG. 3A, where the same parts are not repeated. The difference between the signal processing device 300’ and the signal processing device 300 lies in that the second chopper 220 is coupled between the mixer 250 and the low noise amplifier LNA in the signal processing device 300’. Furthermore, the second chopper 220 is coupled to the input of the mixer 250 and coupled to the output of the low noise amplifier LNA. In this way, the flicker noise generated by the mixer 250 may be first shifted to the second frequency (shifted out), and then paired with another third chopper 230 to perform the shifting back operation of the frequency.

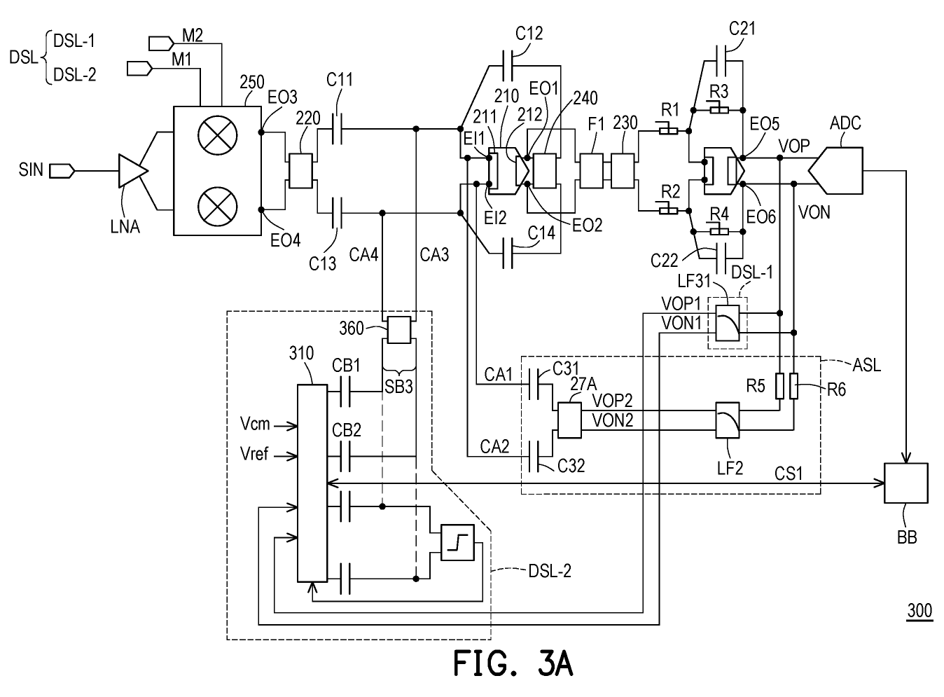

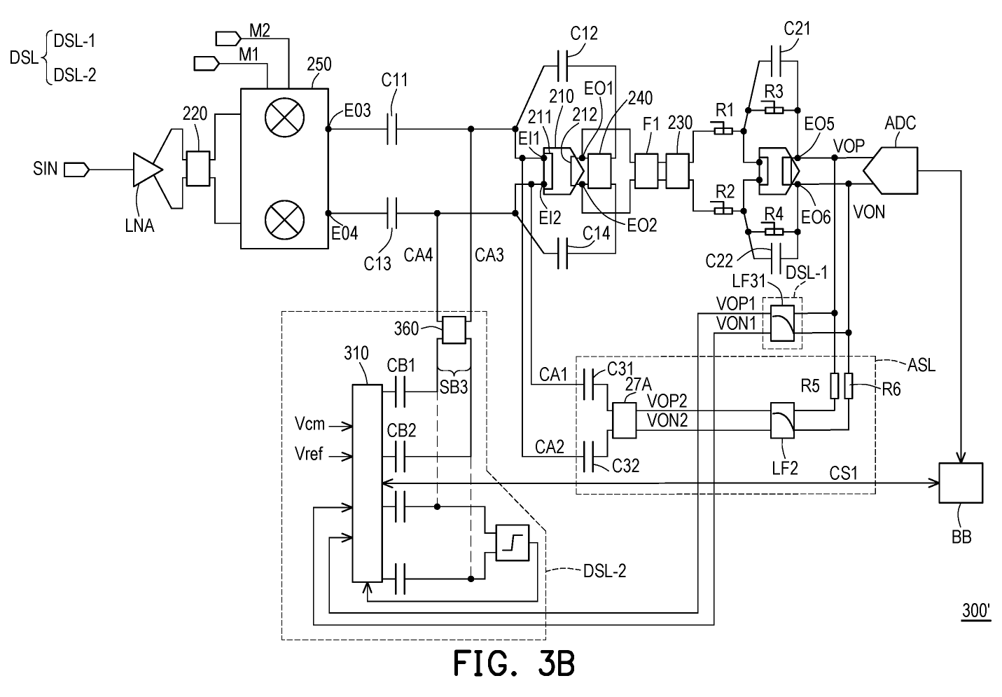

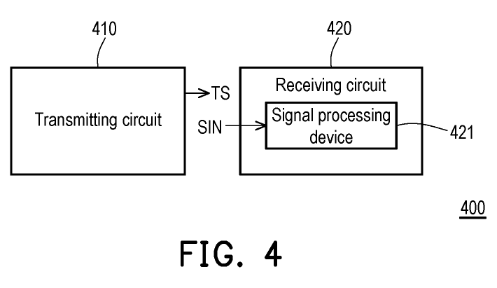

Please refer to FIG. 4, which is a schematic diagram of a signal transceiver device according to an embodiment of the disclosure. A signal transceiver device 400 includes a transmitting circuit 410 and a receiving circuit 420. The transmitting circuit 410 may be configured to continuously transmit a transmission signal TS during a period. The receiving circuit 420 may be configured to continuously receive an input signal SIN during the same period, where the input signal SIN is generated by the transmission signal TS being reflected by an external object. In other words, the transmitting circuit 410 and the receiving circuit 420 of the signal transceiver device 400 may be enabled simultaneously, so that the transmitting circuit 410 and the receiving circuit 420 transmit signals simultaneously. In this embodiment, the signal transceiver device 400 may be, for example, a radar system, and the transmitting circuit 410 and the receiving circuit 420 may be disposed within the same chip. Since the receiving circuit 420 is continuously subjected to interference (such as DC offset or low-frequency flicker noise) caused by the transmitting circuit 410 during the same period, the receiving circuit 420 may include a signal processing device 421 to reduce the impact of the aforementioned interference. The signal processing device 421 may be implemented by using any one of the signal processing devices 100, 200, 200’, 300, or 300’ from the aforementioned embodiments. The relevant details are not elaborated here.

In summary, according to the signal processing device of the disclosure, the paired choppers are embedded between the input and output of the amplifier, and are disposed at multiple positions in the loop of the signal processing device. By these choppers performing different frequency shift-out and shift-back processing, the DC offset value and flicker noise that may be coupled into the signal may be effectively reduced, thereby improving the quality of the transmitted signal.

What is claimed is:

1. A signal processing device, comprising:
a first amplifier, configured to generate a second signal according to a first signal;
two first choppers, embedded between an input end and an output end of the first amplifier, wherein the two first choppers are configured to perform a shifting operation of a first frequency and a shifting back operation of the first frequency, respectively;
a second chopper, coupled to the input end of the first amplifier, and;
a third chopper, coupled to the output end of the first amplifier, wherein the second chopper is configured to perform a shifting operation of a second frequency, the third chopper is configured to perform a shifting back operation of the second frequency, and the first frequency and the second frequency are different.

2. The signal processing device according to claim 1, further comprising:
a fourth chopper, coupled between the output end and the input end of the first amplifier, wherein the fourth chopper is configured to perform the shifting operation of the second frequency, and the third chopper is configured to perform the shifting back operation of the second frequency.

3. The signal processing device according to claim 1, further comprising:
a second amplifier, coupled to the first amplifier, and configured to generate an output signal according to the second signal; and
two fifth choppers, embedded between an input end and an output end of the second amplifier, wherein the two fifth choppers are configured to perform the shifting operation of the first frequency and the shifting back operation of the first frequency.

4. The signal processing device according to claim 3, further comprising:
a DC offset circuit, coupled to the input end of the first amplifier, and configured to adjust a DC voltage level of the first signal according to a control signal.

5. The signal processing device according to claim 4, further comprising:
a first feedback circuit, coupled between the output end of the second amplifier and the DC offset circuit, and configured to generate the control signal according to the output signal.

6. The signal processing device according to claim 5, wherein the first feedback circuit comprises:
a first low-pass filter, receiving the output signal and generating a first filtered output signal; and
a compensation circuit, processing the first filtered output signal to generate a digital control signal based on a calibration signal.

7. The signal processing device according to claim 6, wherein an output end of the compensation circuit has a sixth chopper, the sixth chopper is configured to perform the shifting operation of the second frequency, and the third chopper is configured to perform the shifting back operation of the second frequency.

8. The signal processing device according to claim 3, further comprising:
a second feedback circuit, coupled between the output end of the second amplifier and the input end of the first amplifier, and configured to provide a compensation signal to the input end of the first amplifier according to the output signal.

9. The signal processing device according to claim 8, wherein the second feedback circuit comprises:
a second low-pass filter, receiving the output signal and generating a second filtered output signal; and
a capacitor pair and a seventh chopper, wherein the capacitor pair and the seventh chopper are serially coupled between the second low-pass filter and the input end of the first amplifier, and configured to generate the compensation signal according to the second filtered output signal, the seventh chopper is configured to perform a shifting operation of the second frequency, and the third chopper is configured to perform a shifting back operation of the second frequency.

10. The signal processing device according to claim 2, further comprising:
a first feedback circuit, coupled between an output end of a second amplifier and the input end of the first amplifier, and configured to provide a first compensation signal to the input end of the first amplifier according to an output signal.

11. The signal processing device according to claim 10, wherein the first feedback circuit comprises:
a first low-pass filter, receiving the output signal and generating a first filtered output signal;
a logic circuit, converting the first filtered output signal into a digital converted signal based on a calibration signal, and according to a shared voltage and a reference voltage; and
a capacitor pair and a sixth chopper, wherein the capacitor pair and the sixth chopper are serially coupled between a logic circuit and the input end of the first amplifier, and configured to receive the converted signal and generate the first compensation signal, the sixth chopper is configured to perform a shifting operation of the second frequency, and the third chopper is configured to perform a shifting back operation of the second frequency.

12. The signal processing device according to claim 10, further comprising:
a second feedback circuit, coupled between the output end of the second amplifier and the input end of the first amplifier, and configured to provide a second compensation signal to the input end of the first amplifier according to the output signal.

13. The signal processing device according to claim 12, wherein the second feedback circuit comprises:
a second low-pass filter, receiving the output signal and generating a second filtered output signal; and
a capacitor pair and a seventh chopper, wherein the capacitor pair and the seventh chopper are serially coupled between the second low-pass filter and the input of the first amplifier, and configured to generate an analog second compensation signal according to the second filtered output signal, the seventh chopper is configured to perform a shifting operation of the second frequency, and the third chopper is configured to perform a shifting back operation of the second frequency.

14. The signal processing device according to claim 1, further comprising a mixer, coupled to the input end of the first amplifier, and configured to perform frequency mixing on an input signal to generate the first signal, wherein the second chopper is coupled between an output end of the mixer and the input end of the first amplifier, or, the second chopper is coupled to an input end of the mixer.

15. The signal processing device according to claim 1, wherein the first frequency and the second frequency differ by at least two times.

16. The signal processing device according to claim 3, further comprising:
a filter, coupled between the output end of the first amplifier and the input end of the second amplifier, and the third chopper is coupled between the output end of the filter and the input end of the second amplifier.

17. The signal processing device according to claim 4, further comprising a mixer, coupled to the input end of the first amplifier, and configured to perform frequency mixing on an input signal to generate the first signal, wherein the first signal comprises a first sub-signal, and the DC offset circuit comprises:
a first sub-circuit, receiving the first sub-signal, and comprising:
a first current source, coupled between a power supply voltage and a first output end of the mixer;
a second current source, coupled between the first output end of the mixer and a reference voltage;
a third current source, coupled between the power supply voltage and a first input end of the first amplifier;
a fourth current source, coupled between the first input end of the first amplifier and the reference voltage; and
a first resistor, coupled between the first output end of the mixer and the first input end of the first amplifier,
wherein one of the first current source to the fourth current source is controlled by a first control signal of the control signal.

18. The signal processing device according to claim 17, wherein the first signal further comprises a second sub-signal, and the DC offset circuit further comprises:
a second sub-circuit, receiving the second sub-signal, and comprising:
a fifth current source, coupled between the power supply voltage and a second output end of the mixer;
a sixth current source, coupled between the second output end of the mixer and the reference voltage;
a seventh current source, coupled between the power supply voltage and a second input end of the first amplifier;
an eighth current source, coupled between the second input end of the first amplifier and the reference voltage; and
a second resistor, coupled between the second output end of the mixer and the second input end of the first amplifier,
wherein one of the fifth current source to the eighth current source is controlled by a second control signal of the control signal.

19. The signal processing device according to claim 1, further comprising:
a first series of capacitors, coupled between a first output end and a first input end of the first amplifier; and
a second series of capacitors, coupled between a second output end and a second input end of the first amplifier,
wherein the first amplifier, the first series of capacitors, and the second series of capacitors form a capacitively coupled instrumentation amplifier.

20. A signal transceiver device, comprising:
a transmitting circuit, configured to continuously transmit a transmission signal during a first period; and
a receiving circuit, configured to continuously receive an input signal during the first period, wherein the input signal is generated by the transmission signal being reflected by an external object, and the receiving circuit comprises:
a first amplifier, configured to generate a second signal according to a first signal generated by the input signal;
two first choppers, embedded between an input end and an output end of the first amplifier, and configured to perform a shifting operation of a first frequency and a shifting back operation of the first frequency during the first period;
a second chopper, coupled to the input end of the first amplifier, and;
a third chopper, coupled to the output end of the first amplifier, wherein the second chopper is configured to perform a shifting operation of a second frequency during the first period, the third chopper is configured to perform a shifting back operation of the second frequency during the first period, and the first frequency and the second frequency are different.
